(19) United States
(12) Patent Application Publication
(10) Pub. No.: US 2023/0215749 A1
(43) Pub. Date: Jul. 6, 2023

(54) LOGISTICS SYSTEM IN FABRICATION FACILITY

(71) Applicant: SEMES CO., LTD., Cheonan-si (KR)

(72) Inventors: Jin Ho LEE, Gwangmyeong-si (KR); Jong Won JUNG, Gwangmyeong-si (KR)

(73) Assignee: SEMES CO., LTD., Cheonan-si (KR)

(21) Appl. No.: 18/083,659

(22) Filed: Dec. 19, 2022

(30) Foreign Application Priority Data
Dec. 30, 2021 (KR) 10-2021-0192606
Feb. 17, 2022 (KR) 10-2022-0020817

(51) Int. Cl. H01L 21/677; G06Q 10/083; G06Q 10/087

(52) U.S. Cl. CPC H01L 21/67727; H01L 21/67715; H01L 21/67733; H01L 21/67724; G06Q 10/083; G06Q 10/087; B66C 19/00

(57) ABSTRACT

An embodiment of the present disclosure aims to provide a logistics system capable of preventing congestion of transport vehicles in a specific section of a fabrication facility. According to the present disclosure, a logistics system in a fabrication facility includes a stocker equipment that is located near a central passage and stores an article, and a rail that provides a travel path of a transport vehicle that loads and unloads the article to the stocker equipment. The stocker equipment includes a load port disposed on a side opposite to the central passage and a rack that provides a space for storing the article. The rail includes a central rail formed along the central passage and a branch rail that is branched from the central passage and formed along the periphery of the load port.

### CROSS REFERENCE TO RELATED APPLICATION

The present application claims priorities to Korean Patent Application No. 10-2021-0192606, filed Dec. 30, 2021 and Korean Patent Application No. 10-2022-0020817, filed Feb. 17, 2022, the entire contents of which is incorporated by reference herein for all purposes.

### BACKGROUND OF THE INVENTION

### Field of the Invention

The present disclosure relates to a logistics system in a fabrication facility for efficient article transport.

### Description of the Related Art

A semiconductor or display fabrication process is a process of manufacturing a final product through tens to hundreds of processing processes on a substrate (wafer or glass), and can be executed by a fabrication facility that performs each process. When the process at a specific fabrication facility is completed, the article (substrate) can be transported to the next fabrication facility to proceed with the next process, and then can be stored in a storage facility for a predetermined period.

A logistics system in a fabrication facility refers to a system that transports or stores articles for fabrication processes as described above, and can be roughly divided into a transport system that transports articles and a storage facility that stores articles. An overhead hoist transport (OHT) system that travels along a rail installed on the ceiling is applied to the fabrication facility in the logistics system.

In order to increase the production efficiency of the fabrication facility, it is becoming important to quickly transport articles between manufacturing equipment. In order to quickly transport articles, it is necessary to increase the speed of a transport vehicle that transfers the articles and efficiently set a travel path on which the transport vehicle travels. In particular, in designing the travel path, it is necessary to remove a section in which where the transport vehicles are congested.

### SUMMARY OF THE INVENTION

An embodiment of the present disclosure aims to provide a logistics system capable of preventing congestion of transport vehicles in a specific section of a fabrication facility.

According to an aspect of the present disclosure, a logistics system in a fabrication facility includes a stocker equipment that is located near a central passage and stores an article, and a rail that provides a travel path of a transport vehicle that loads and unloads the article to the stocker equipment. The stocker equipment includes a load port disposed on a side opposite to the central passage and a rack that provides a space for storing the article. The rail includes a central rail formed along the central passage and a branch rail that is branched from the central passage and formed along the periphery of the load port.

According to an embodiment of the present disclosure, the branch rail may be configured to be branched from the central passage, form along the periphery of the load port, and be joined to the central passage.

According to the embodiment of the present disclosure, the transport vehicle may travel from the central rail to the branch rail to load and unload an article to the load port.

According to the embodiment of the present disclosure, the central rail may be configured by a plurality of lines in a horizontal direction.

According to the embodiment of the present disclosure, the central rail and the branch rail may be configured by multi-layer lines in a vertical direction.

According to the embodiment of the present disclosure, the load port may be formed under a lower layer line of the branch rail configured by the multi-layer line.

According to another aspect of the present disclosure, a logistics system in a fabrication facility includes a plurality of stocker equipment arranged on both sides of a central passage and a rail that provides a travel path of a transport vehicle that loads and unloads an article to the stocker equipment. The stocker equipment includes a load port disposed on a side opposite to the central passage and a rack that provides a space for storing the article. The rail includes a central rail formed along the central passage and a branch rail that is branched from the central passage and famed along the periphery of the load port.

According to an embodiment of the present disclosure, the branch rail may be configured to be branched from the central passage, form along the periphery of the load port, and be joined to the central passage.

According to the embodiment of the present disclosure, the transport vehicle may travel from the central rail to the branch rail to load and unload an article to the load port.

According to the embodiment of the present disclosure, the central rail may be configured by a plurality of lines in a horizontal direction.

According to the embodiment of the present disclosure, the central rail and the branch rail may be configured by multi-layer lines in a vertical direction.

According to the embodiment of the present disclosure, the load port may be formed under a lower layer line of the branch rail configured by the multi-layer line.

According to still another aspect of the present disclosure, a logistics system in a fabrication facility includes a plurality of stocker equipment arranged on both sides of a central passage, a rail that provides a travel path of a transport vehicle that loads and unloads an article to the stocker equipment, and an interface module that is formed across the central passage to convey the article between the stocker equipment. The stocker equipment includes a load port disposed on a side opposite to the central passage and a rack that provides a space for storing the article. The rail includes a central rail formed along the central passage and a branch rail that is branched from the central passage and formed along the periphery of the load port. The interface module is configured to convey the article put into the load port of the stocker equipment to an opposite stocker equipment.

According to an embodiment of the present disclosure, the branch rail may be configured to be branched from the central passage, form along the periphery of the load port, and be joined to the central passage.

According to the embodiment of the present disclosure, the transport vehicle may travel from the central rail to the branch rail to load and unload an article to the load port.

According to the embodiment of the present disclosure, the central rail may be configured by a plurality of lines in a horizontal direction.

According to the embodiment of the present disclosure, the interface module may include a pair of conveyors that convey the article in opposite directions.

According to the embodiment of the present disclosure, the central rail and the branch rail may be configured by multi-layer lines in a vertical direction.

According to the embodiment of the present disclosure, the load port may be formed under a lower layer line of the branch rail configured by the multi-layer line.

According to the embodiment of the present disclosure, the interface module may be formed under a lower layer line of the branch rail.

According to the present disclosure, in a logistics system in a fabrication facility, a load port of a stocker equipment is located on a side opposite to a central passage, and a branch rail is branched from a central rail and is formed along the load port. Thus, it is possible to prevent congestion caused by a transport vehicle that loads and unloads an article to the stocker equipment, around the central passage.

The effects of the present disclosure are not limited to the effects described above, and effects not mentioned can be clearly understood by those skilled in the art, from the specification and the attached drawings.

### BRIEF DESCRIPTION OF THE DRAWINGS

The above and other objectives, features, and other advantages of the present disclosure will be more clearly understood from the following detailed description taken in conjunction with the accompanying drawings, in which:

FIG. 1 illustrates a logistics system of a fabrication facility to which the present disclosure can be applied;

FIG. 2 is a diagram illustrating congestion that occurs when a transport vehicle loads and unloads an article to a stocker equipment;

FIGS. 3 and 4 illustrate a configuration of a logistics system in a fabrication facility according to an aspect of the present disclosure;

FIGS. 5 and 6 illustrate a configuration of a logistics system in a fabrication facility according to another aspect of the present disclosure;

FIGS. 7 and 8 illustrate a configuration of a logistics system in a fabrication facility according to still another aspect of the present disclosure;

FIGS. 9 to 12 illustrate examples of conveying an article through a central passage;

FIG. 13 illustrates a case where an article is transported between bays by using the stocker equipment; and

FIG. 14 illustrates a case where an article is transported between lines by using the stocker equipment.

### DESCRIPTION OF THE EMBODIMENTS

Hereinafter, embodiments of the present disclosure will be described in detail with reference to the attached drawings to be easily implemented by those skilled in the art. The present disclosure may be implemented in various different forms and is not limited to the embodiments described herein.

In order to clearly describe the present disclosure, parts that are not related to the description will be omitted, and the same or similar components in this specification are denoted by the same reference sign.

In addition, in various embodiments, a component having the same configuration will be described only in a representative embodiment by using the same reference sign, and only a configuration that is different from that of the representative embodiment will be described in other embodiments.

In the entirety of this specification, a sentence that a portion is “connected (or coupled) to” another portion includes not only a case of “being directly connected (coupled)” but also a case of “being indirectly connected (coupled) with other members interposed therebetween”. In addition, a sentence that a portion “includes” a component means that it may further include another component rather than excluding other components unless a particularly opposite statement is made.

Unless otherwise defined, all terms used herein, including technical or scientific terms, have the same meaning as generally understood by those skilled in the art. Terms such as those defined in a commonly used dictionary should be construed as having a meaning consistent with the meaning of the relevant technology, and should not be construed as an ideal or excessively formal meaning unless explicitly defined in this application.

A logistics system for efficient article transport in a fabrication facility according to the present disclosure will be described below.

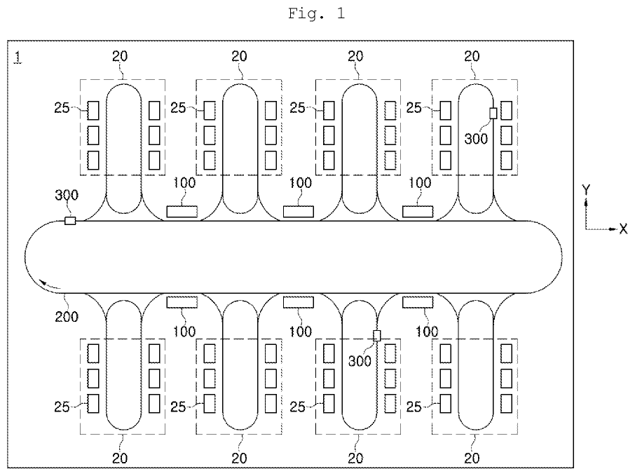

FIG. 1 illustrates a logistics system of a fabrication facility to which the present disclosure can be applied. A semiconductor fabrication facility that manufactures semiconductor products will be described below as an example of a fabrication facility to which the present disclosure is applied. The range of fabrication facilities to which the present disclosure can be applied is not limited to a specific type and can be applied to fabrication facilities of various industries. For example, the logistics system according to the present disclosure can be applied to other types of fabrication facilities that produce products such as display panels, electronic devices, automobiles, and secondary batteries.

A fabrication facility 1 includes one or more clean rooms, and manufacturing equipment 25 that execute semiconductor fabrication processes can be installed in each clean room. Generally, a finally processed substrate may be completed by repeatedly executing a plurality of fabrication processes on a substrate (for example, a wafer). After the fabrication process is completed at a specific semiconductor manufacturing equipment 25, the substrate is transported to the manufacturing equipment 25 for the next fabrication process. Here, the wafer can be transported in a state of being stored in a transport container (for example, a front opening unified pod, FOUP) capable of accommodating a plurality of substrates. The transport container in which wafers are stored can be transported by a transport vehicle 300. The transport vehicle 300 may be referred to as an overhead hoist transport (OHT) that travels along a rail 200 installed on the ceiling.

With reference to FIG. 1, the manufacturing equipment 25 that executes a process in the fabrication facility 1 is installed, and the transport vehicle 300 that conveys an article between manufacturing equipment 25 and the rail 200 that provides a travel path of the transport vehicle 300 are provided. Here, when the transport vehicle 300 transports an article between the manufacturing equipment 25, the article may be immediately transported from the specific manufacturing equipment 25 to another manufacturing equipment 25, or the article may be transported to another manufacturing equipment after being stored in a stocker equipment 100. In FIG. 1, an upward direction (Y direction) based on a central passage 10 can be referred to as the north direction and a downward direction (−Y direction) can be referred to as the south direction. A leftward direction (−X direction) based on a north-south direction can be referred to as the west direction, and a rightward direction (X direction) can be referred to as the east direction.

With reference to FIG. 1, the rail 200 that forms a circulation path along the central passage 10 is installed, and the rail 200 branched from the central passage 10 forms a circulation path again. The manufacturing equipment 25 are arranged along the periphery of the circulation path of the rail 200, thereby constituting one bay 20. In other words, the central passage 10 is formed at the center of the fabrication facility 1, and a plurality of bays 20 are formed around the central passage 10. Here, semiconductor manufacturing equipment 25 that execute the same or similar semiconductor processing processes may be arranged in each bay 20 or a set of adjacent bays 20. For example, an etching process facility can be disposed in a bay 20 located in the northwest, an exposure process facility can be disposed in a bay 20 located in the northeast, a deposition process facility can be disposed in a bay 20 located in the southwest, and an oxide film process facility can be disposed in the bay 20 located in the southeast.

The stocker equipment 100 that stores an article can be arranged around the central passage 10. The stocker equipment 100 is a warehouse for storing articles, and is set to store a container that stores wafers on which a process that have been completed in the specific manufacturing equipment 25, before the container is conveyed to another manufacturing equipment 25. The stocker equipment 100 includes a load port 110 that loads an article and a rack 120 that provides a space for storing an article. The load port 110 receives an article from the transport vehicle 300 located above or discharges an article to be picked up by the transport vehicle 300. The rack 120 is configured by a plurality of shelves for storing articles received in the load port 110. A crane or a robot that is disposed in a vertical and horizontal direction in an internal space of the rack 120 and conveys an article in the rack 120 can be provided in the rack 120.

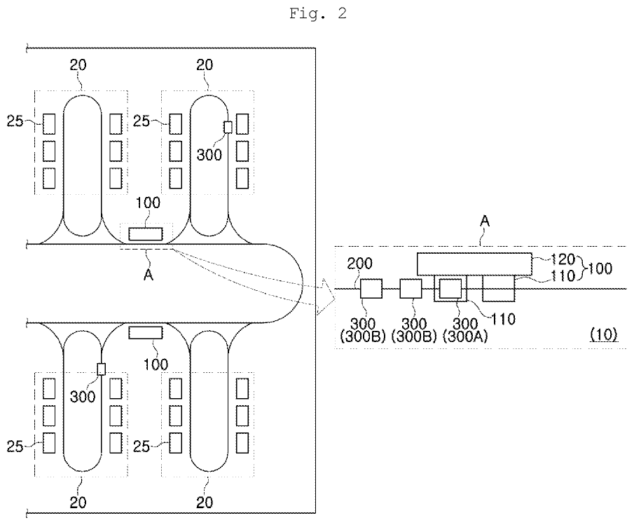

The stocker equipment 100 is generally disposed around the central passage 10. In order to load and unload an article to the stocker equipment 100, the transport vehicle 300 stops around the stocker equipment 100 and then loads an article to the load port 110 or unloads an article from the load port 110. At this time, congestion may occur due to the stop of the transport vehicle 300 in an area A around the stocker equipment 100, as illustrated in FIG. 2. With reference to FIG. 2, when a transport vehicle 300A stops to load and unload an article to the stocker equipment 100, a transport vehicle 300B located behind the transport vehicle 300A needs to wait until the article loading and unloading of the transport vehicle 300A are completed. Many transport vehicles 300A travel through the central passage 10. A transport vehicle 300 that moves from a specific bay 20 to another bay 20 needs to pass through the rail 200 around the central passage 10. In particular, the transport vehicle 300 that moves from the south bay 20 to the north bay 20 needs to move via the rail 200 around the central passage 10. In other words, many transport vehicles 300 need to travel on the rail 200 around the central passage 10, and congestion occurs on the rail 200 of the central passage 10 because the transport vehicle 300 stops to load and unload an article to the stocker equipment 100.

If congestion occurs on the rail 200 of the central passage 10, the overall logistics flow may be delayed, which may cause a decrease in the production efficiency of the fabrication facility 1. Therefore, an embodiment of the present disclosure provides a logistics system capable of preventing an occurrence of congestion on the rail 200 of the central passage 10. Furthermore, another embodiment of the present disclosure provides a logistics system capable of smoothly conveying articles between the south side and the north side based on the central passage 10.

According to an aspect of the present disclosure, a logistics system in a fabrication facility 1 includes a stocker equipment 100 that is located near a central passage 10 and stores an article, and a rail 200 that provides a travel path of a transport vehicle 300 that loads and unloads the article to the stocker equipment 100. The stocker equipment 100 includes a load port 110 disposed on a side opposite to the central passage 10 and a rack 120 that provides a space for storing an article. The rail 200 includes a central rail 210 famed along the central passage 10 and a branch rail 220 that is branched from the central passage 10 and formed along the periphery of the load port 110.

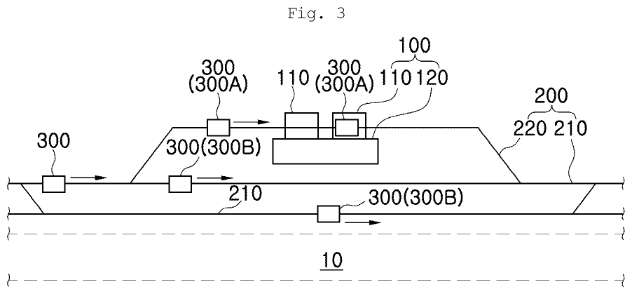

With reference to FIG. 3, the load port 110 of the stocker equipment 100 is not located around the central passage 10, but on the side opposite to the central passage 10. The central rail 210 is formed around the central passage 10. The branch rail 220 that is branched from the central rail 210 is configured to extend to the side opposite to the central passage 10, to be formed along the load port 110 of the stocker equipment 100, and to be joined to the central passage 10 again.

As illustrated in FIG. 3, the transport vehicle 300A that loads and unloads an article to the stocker equipment 100 may travel from the central rail 210 to the branch rail 220, and then stop around the load port 110, and load or unload the article to or from the load port 110. Thus, the transport vehicle 300B that travels through the central passage 10 can travel without being blocked by the transport vehicle 300A that loads and unloads an article to the stocker equipment 100, and can prevent the occurrence of congestion around the central passage 10.

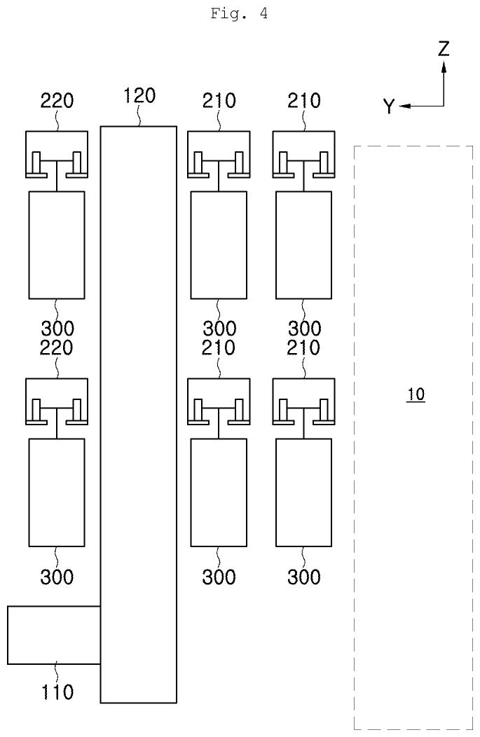

As an example, the central rail 210 is configured by a plurality of lines in the horizontal direction (Y direction). With reference to FIGS. 3 and 4, the central rail 210 may be configured by lines arranged in parallel around the central passage 10. By forming multiple lines around the central passage 10 with a high traffic volume of the transport vehicles 300, it is possible to cause the transport vehicle 300 to travel through an additional line even if congestion has occurred on one line. By forming a plurality of lines in the horizontal direction (Y direction) as illustrated in FIGS. 3 and 4, it is possible to prevent the occurrence of congestion on the central passage 10 and to quickly transport an article.

As an example, the central rail 210 and the branch rail 220 are configured by multi-layer lines in the vertical direction (Z direction). With reference to FIG. 4, the central rail 210 and the branch rail 220 may be configured by lines arranged in parallel in the vertical direction (Z direction) around the central passage 10. In other words, the central rail 210 and the branch rail 220 may be configured by multi-layer lines. Since the central rail 210 and the branch rail 220 are formed by a plurality of lines not only in the horizontal direction (Y direction) but also in the vertical direction (Z direction), it is possible to cause the transport vehicle 300 to travel through an additional line even if congestion has occurred on one line. By forming a plurality of lines in the horizontal direction (Y direction) as illustrated in FIG. 4, it is possible to prevent the occurrence of congestion on the central passage 10 and to quickly transport an article.

As an example, the load port 110 may be formed under the lower layer line of the branch rail 220 configured by the multi-layer line. As illustrated in FIG. 4, the load port 110 is located under the lower layer line of the branch rail 220. The transport vehicle 300A that intends to load and unload an article to the load port 110 can enter the branch rail 220 of the lower layer line and stops around the load port 110. Then, the transport vehicle 300A can load or unload an article. The load port 110 may be located at the lower height of the branch rail 220 in the upper layer, and a transport vehicle 300 that travels on the branch rail 220 in the upper layer may load and unload an article to the upper load port 110.

In a logistics system in a fabrication facility according to another aspect of the present disclosure, the stocker equipment 100 may be arranged on both sides of the central passage 10, and the load port 110 may be located on a side opposite to the central passage 10 in each stocker equipment 100.

A logistics system in a fabrication facility 1 according to still another aspect of the present disclosure includes a plurality of stocker equipment 100 arranged on both sides of the central passage 10 and a rail 200 that provides a travel path of a transport vehicle 300 that loads and unloads an article to the stocker equipment 100. The stocker equipment 100 includes a load port 110 disposed on a side opposite to the central passage 10 and a rack 120 that provides a space for storing an article. The rail 200 includes a central rail 210 formed along the central passage 10 and a branch rail 220 that is branched from the central passage 10 and formed along the periphery of the load port 110.

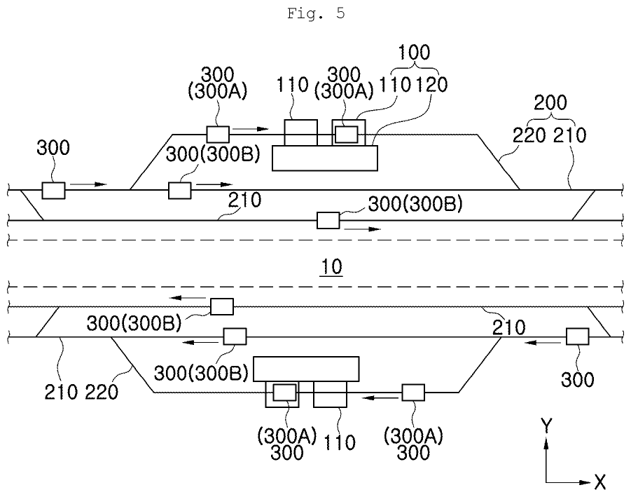

With reference to FIG. 5, the load ports 110 of the stocker equipment 100 arranged on both sides around the central passage 10 are not arranged to face the central passage 10, but are arranged on the side opposite to the central passage 10. The central rail 210 is formed around the central passage 10. The branch rail 220 that is branched from the central rail 210 is configured to extend to the side opposite to the central passage 10, to be formed along the load port 110 of the stocker equipment 100, and to be joined to the central passage 10 again.

As illustrated in FIG. 5, the transport vehicle 300A that loads and unloads an article to the stocker equipment 100 may travel from the central rail 210 to the branch rail 220, and then stop around the load port 110, and load or unload the article to or from the load port 110. Thus, the transport vehicle 300B that travels through the central passage 10 can travel without being blocked by the transport vehicle 300A that loads and unloads an article to the stocker equipment 100, and can prevent the occurrence of congestion around the central passage 10.

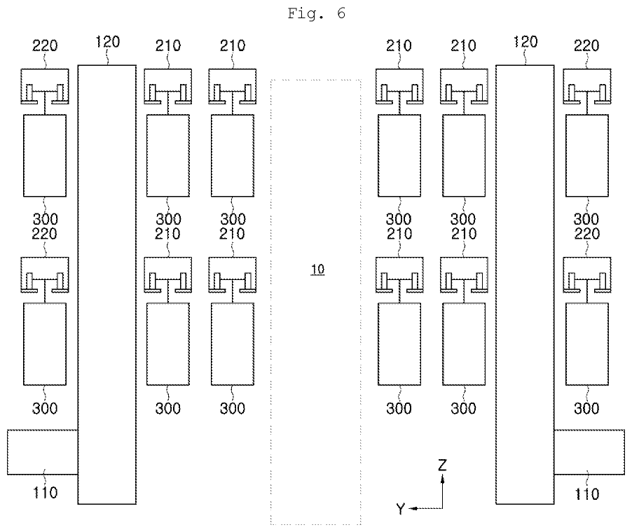

As an example, the central rail 210 is configured by a plurality of lines in the horizontal direction (Y direction). With reference to FIGS. 5 and 6, the central rail 210 may be configured by lines arranged in parallel around the central passage 10. By forming multiple lines around the central passage 10 with a high traffic volume of the transport vehicles 300, it is possible to cause the transport vehicle 300 to travel through an additional line even if congestion has occurred on one line. By forming a plurality of lines in the horizontal direction (Y direction) as illustrated in FIGS. 5 and 6, it is possible to prevent the occurrence of congestion on the central passage 10 and to quickly transport an article.

As an example, the central rail 210 and the branch rail 220 are configured by multi-layer lines in the vertical direction (Z direction). With reference to FIG. 6, the central rail 210 and the branch rail 220 may be configured by lines arranged in parallel in the vertical direction (Z direction) around the central passage 10. In other words, the central rail 210 and the branch rail 220 may be configured by multi-layer lines. Since the central rail 210 and the branch rail 220 are formed by a plurality of lines not only in the horizontal direction (Y direction) but also in the vertical direction (Z direction), it is possible to cause the transport vehicle 300 to travel through an additional line even if congestion has occurred on one line. By forming a plurality of lines in the horizontal direction (Y direction) as illustrated in FIG. 6, it is possible to prevent the occurrence of congestion on the central passage 10 and to quickly transport an article.

As an example, the load port 110 may be formed under the lower layer line of the branch rail 220 configured by the multi-layer line. As illustrated in FIG. 6, the load port 110 is located under the lower layer line of the branch rail 220. The transport vehicle 300A that intends to load and unload an article to the load port 110 can enter the branch rail 220 of the lower layer line and stops around the load port 110. Then, the transport vehicle 300A can load or unload an article. The load port 110 may be located at the lower height of the branch rail 220 in the upper layer, and a transport vehicle 300 that travels on the branch rail 220 in the upper layer may load and unload an article to the upper load port 110.

Meanwhile, in a logistics system in a fabrication facility according to still another aspect of the present disclosure, stocker equipment 100 may be arranged on both sides of a central passage 10, and an interface module 250 that transports an article between the stocker equipment 100 on both the sides may be provided. Articles can be conveyed directly through the interface module 250 in the north-south direction (Y direction).

A logistics system in a fabrication facility 1 according to still another aspect of the present disclosure includes a plurality of stocker equipment 100 arranged on both sides of a central passage 10, a rail 200 that provides a travel path of a transport vehicle 300 that loads and unloads an article to the stocker equipment 100, and an interface module 250 that is formed across the central passage 10 and conveys an article between the stocker equipment 100. The stocker equipment 100 includes a load port 110 disposed on a side opposite to the central passage 10 and a rack 120 that provides a space for storing an article. The rail 200 includes a central rail 210 formed along the central passage 10 and a branch rail 220 that is branched from the central passage 10 and formed along the periphery of the load port 110. The interface module 250 is configured to convey an article put into the load port 110 of the stocker equipment 100 to an opposite stocker equipment 100.

As an example, when an article is conveyed from the south bay 20 to the north bay 20 (or in the opposite direction), the article may be unloaded to the north stocker equipment 100, and then the article may be transferred to the south stocker equipment 100 through the interface module 250. Furthermore, a transport vehicle 300 located around the south stocker equipment 100 may pick up the article and then convey the article. In this case, since the transport vehicle 300 does not need to circulate the rail 200 around the central passage 10, it is possible to reduce the number of transport vehicles 300 that travel around the central passage 10. By reducing the number of transport vehicles 300 that travel around the central passage 10, it is possible to prevent the occurrence of congestion on the central passage 10.

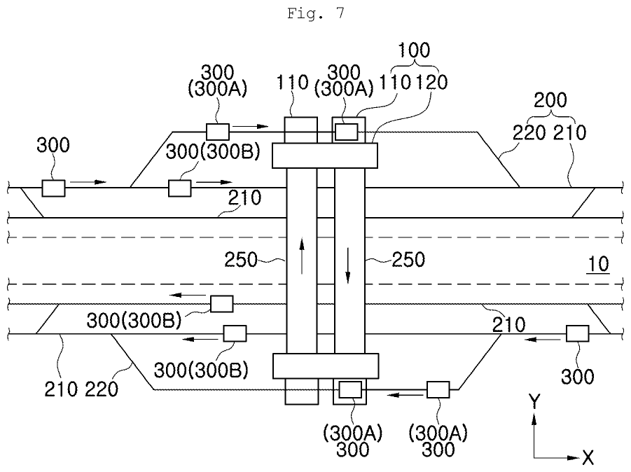

With reference to FIG. 7, the load ports 110 of the stocker equipment 100 arranged on both sides around the central passage 10 are not arranged to face the central passage 10, but are arranged on the side opposite to the central passage 10. The central rail 210 is formed around the central passage 10. The branch rail 220 that is branched from the central rail 210 is configured to extend to the side opposite to the central passage 10, to be formed along the load port 110 of the stocker equipment 100, and to be joined to the central passage 10 again. The interface module 250 is configured to convey an article between the north stocker equipment 100 and the south stocker equipment 100.

As illustrated in FIG. 7, the transport vehicle 300A that loads and unloads an article to the stocker equipment 100 may travel from the central rail 210 to the branch rail 220, and then stop around the load port 110, and load or unload the article to or from the load port 110. Thus, the transport vehicle 300B that travels through the central passage 10 can travel without being blocked by the transport vehicle 300A that loads and unloads an article to the stocker equipment 100, and can prevent the occurrence of congestion around the central passage 10.

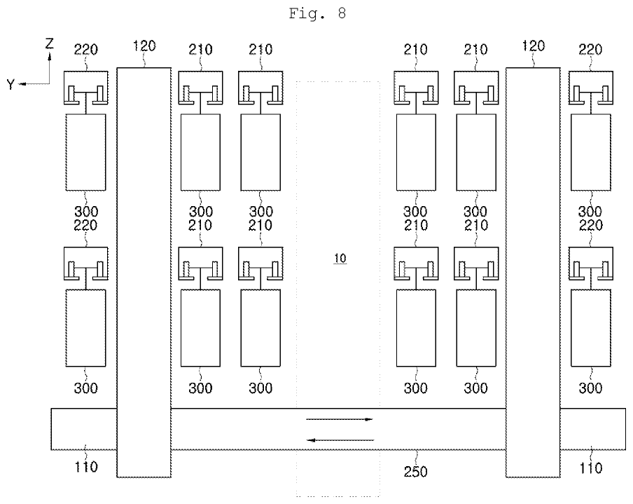

As an example, the central rail 210 is configured by a plurality of lines in the horizontal direction (Y direction). With reference to FIGS. 7 and 8, the central rail 210 may be configured by lines arranged in parallel around the central passage 10. By forming multiple lines around the central passage 10 with a high traffic volume of the transport vehicles 300, it is possible to cause the transport vehicle 300 to travel through an additional line even if congestion has occurred on one line. By forming a plurality of lines in the horizontal direction (Y direction) as illustrated in FIGS. 7 and 8, it is possible to prevent the occurrence of congestion on the central passage 10 and to quickly transport an article.

As an example, the interface module 250 may include a pair of conveyors that convey the article in opposite directions. In other words, the pair of conveyors configured to convey articles in opposite directions can be coupled to the stocker equipment 100 located on the opposite sides based on the central passage 10. The interface module 250 may be connected to the load port 110 of each stocker equipment 100 and transfer an article to the opposite stocker equipment 100. The type of conveyor that can be applied as the interface module 250 of the present disclosure is not limited. The interface module 250 can be implemented not only in the form of a conveyor but also in the form of a saddle that receives and moves an article individually.

As an example, the central rail 210 and the branch rail 220 are configured by multi-layer lines in the vertical direction (Z direction). With reference to FIG. 8, the central rail 210 and the branch rail 220 may be configured by lines arranged in parallel in the vertical direction (Z direction) around the central passage 10. In other words, the central rail 210 and the branch rail 220 may be configured by multi-layer lines. Since the central rail 210 and the branch rail 220 are formed by a plurality of lines not only in the horizontal direction (Y direction) but also in the vertical direction (Z direction), it is possible to cause the transport vehicle 300 to travel through an additional line even if congestion has occurred on one line. By forming a plurality of lines in the horizontal direction (Y direction) as illustrated in FIG. 8, it is possible to prevent the occurrence of congestion on the central passage 10 and to quickly transport an article.

As an example, the load port 110 may be formed under the lower layer line of the branch rail 220 configured by the multi-layer line. As illustrated in FIG. 8, the load port 110 is located under the lower layer line of the branch rail 220. The transport vehicle 300A that intends to load and unload an article to the load port 110 can enter the branch rail 220 of the lower layer line and stops around the load port 110. Then, the transport vehicle 300A can load or unload an article. The load port 110 may be located at the lower height of the branch rail 220 in the upper layer, and a transport vehicle 300 that travels on the branch rail 220 in the upper layer may load and unload an article to the upper load port 110.

As an example, the interface module 250 may be formed under the lower layer line of the branch rail 220. As illustrated in FIG. 8, the interface module 250 may be installed at the same or similar height as the load port 110 and transfer an article loaded on the load port 110 to the opposite stocker equipment 100. The interface module 250 may be located at the lower height of the branch rail 220 and convey an article transferred from the transport vehicle 300 that travels on the upper layer rail to the opposite stocker equipment 100.

Regarding the scope of the present disclosure, various examples of conveying an article through the central passage 10 can be applied to the present disclosure in addition to the interface module 250 of the type as illustrated in FIG. 8.

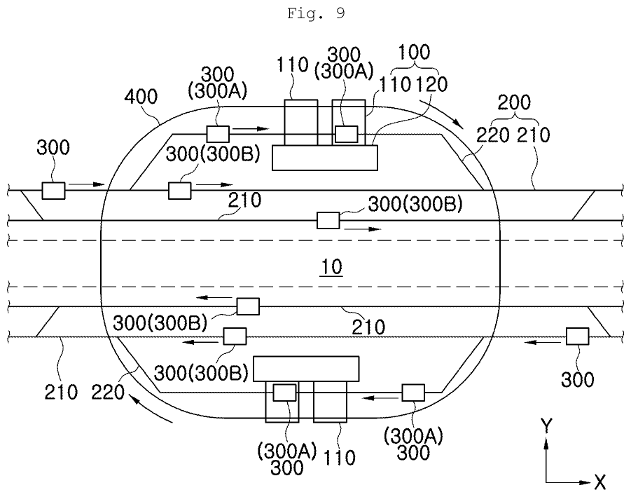

FIGS. 9 to 12 illustrate examples of conveying an article through the central passage 10.

As illustrated in FIG. 9, a circulating conveyor 400 may be configured to circulate between the stocker equipment 100 with sandwiching the central passage 10. The circulating conveyor 400 may be connected to the load port 110 of the stocker equipment 100 with sandwiching the central passage 10 and convey an article to the opposite stocker equipment 100. The article settled in the load port 110 of the stocker equipment 100 can move along the circulating conveyor 400 in a clockwise or counterclockwise direction and be transferred to the opposite stocker equipment 100.

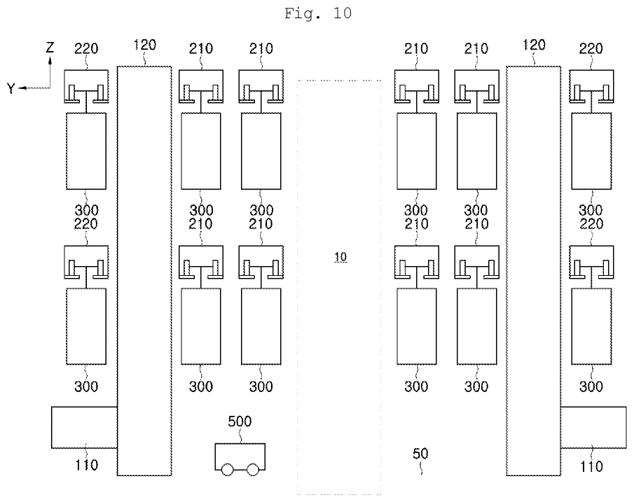

Also, as illustrated in FIG. 10, an article may be conveyed by using a mobile robot 500 that moves back and forth between stocker equipment 100 with sandwiching the central passage 10. With reference to FIG. 10, the mobile robot 500 may travel along a path on the ground 50 and may be equipped with a mechanism for loading and unloading an article. The mobile robot 500 is configured to move back and forth between the stocker equipment 100 through the central passage 10, and may convey an article from the stocker equipment 100 on one side to the stocker equipment 100 on the opposite side.

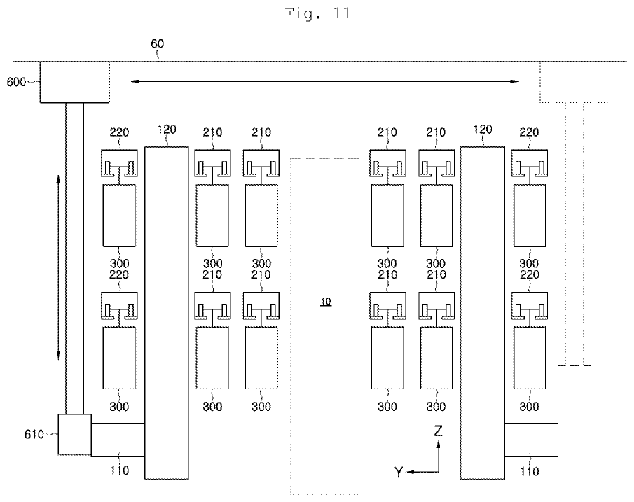

An article may be conveyed between stocker equipment 100 through the central passage 10 by using a crane 600 installed on the ceiling 60 as illustrated in FIG. 11. The crane 600 is configured to move along a path installed in the ceiling 60, and a pickup mechanism 610 coupled to the crane 600 can pick up an article settled in the load port 110 of the stocker equipment 100 and convey the article to the load port 110 of the stocker equipment 100 located on the opposite side.

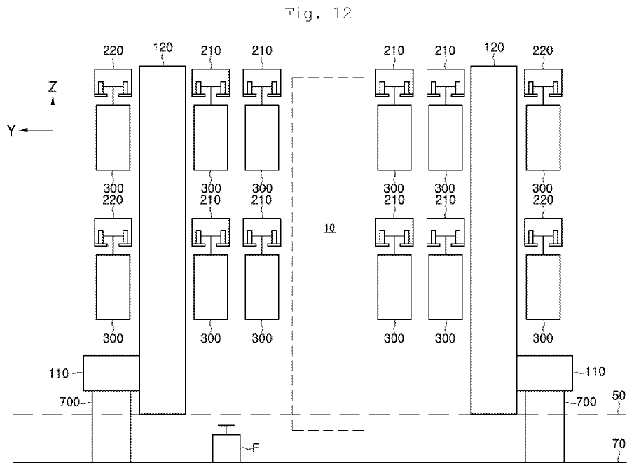

Also, an article may be conveyed along an underground path 70 formed between stocker equipment 100 with sandwiching the central passage 10 as illustrated in FIG. 12. With reference to FIG. 12, a lifting mechanism 700 is connected to the load port 110 of the stocker equipment 100, and an article F settled in the load port 110 can be lowered by the lifting mechanism 700 and moved to the stocker equipment 100 on the opposite side along the underground path 70. The underground path 70 can be implemented by conveyors or birds provided underground.

Regarding the scope of the present disclosure, an article can be conveyed from a bay to another bay by using an interface transport path of the stocker equipment 100, or an article can be conveyed from a specific production line in the fabrication facility 1 to another production line partitioned by a wall.

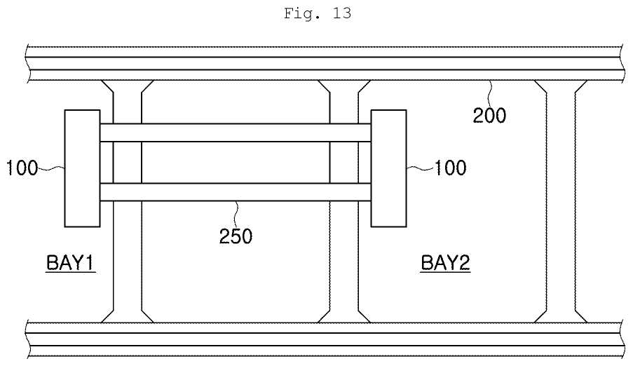

As illustrated in FIG. 13, an article can be conveyed through the interface module 250 connected between the stocker equipment 100 located in a first bay BAY1 and the stocker equipment 100 located in a second bay BAY2.

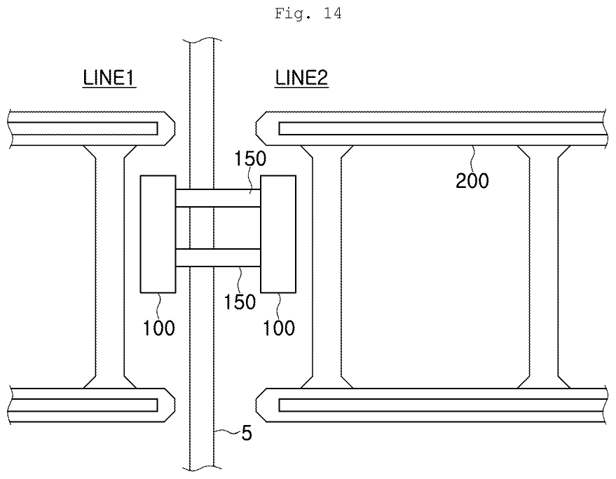

Also, as illustrated in FIG. 14, in order to convey an article between a first production line LINE1 and a second production line LINE2 partitioned by a wall 5, the interface module 250 may be configured between the stocker equipment 100 located in the first production line LINE1 and the stocker equipment 100 located in the second production line LINE2. An article can be moved between the first production line LINE1 and the second production line LINE2 through the interface module 250 provided between the stocker equipment 100.

Regarding the scope of the present disclosure, the present disclosure can be applied to a case where an article is conveyed by using a load port of another facility, in addition to the load port 110 of the stocker equipment 100.

It will be apparent that the present embodiment and the drawings attached to this specification just clearly represent a part of the technical spirit included in the present disclosure, and all modification examples and specific embodiments that can be easily inferred by those skilled in the art within the scope of the technical spirit contained in the specification and drawings of the present disclosure are included in the scope of the present disclosure.

Therefore, the spirit of the present disclosure should not be limited to the described embodiments, and not only the claims to be described later, but also all those that have equal or equivalent modifications to the claims will be said to belong to the scope of the spirit of the present disclosure.

Those skilled in the art should understand that the present disclosure may be embodied in other specific forms without changing the technical spirit or essential characteristics thereof, so the embodiments described above are illustrative in all aspects and are not restrictive.

It will be apparent that the present embodiment and the drawings attached to this specification just clearly represent a part of the technical spirit included in the present disclosure, and all modification examples and specific embodiments that can be easily inferred by those skilled in the art within the scope of the technical spirit contained in the specification and drawings of the present disclosure are included in the scope of the present disclosure.

Therefore, the spirit of the present disclosure should not be limited to the described embodiments, and not only the claims to be described later, but also all those that have equal or equivalent modifications to the claims will be said to belong to the scope of the spirit of the present disclosure.

What is claimed is:

1. A logistics system in a fabrication facility, the logistics system comprising:
a stocker equipment that is located near a central passage and store an article, the stocker equipment including a load port displaced on a side opposite to the central passage, and a rack that provides a space for storing the article; and
a rail that provides a travel path of a transport vehicle that loads and unloads the article to the stocker equipment, the rail including a central rail formed along the central passage, and a branch rail that is branched from the central passage and formed along a periphery of the load port.

2. The logistics system in the fabrication facility according to claim 1, wherein
the branch rail is configured to be branched from the central passage, form along the periphery of the load port, and be joined to the central passage.

3. The logistics system in the fabrication facility according to claim 1, wherein
the transport vehicle travels from the central rail to the branch rail to load and unload the article to the load port.

4. The logistics system in the fabrication facility according to claim 1, wherein
the central rail is configured by a plurality of lines in a horizontal direction.

5. The logistics system in the fabrication facility according to claim 1, wherein
the central rail and the branch rail are configured by multi-layer lines along a vertical direction.

6. The logistics system in the fabrication facility according to claim 5, wherein
the load port is formed under a lower layer line of the branch rail configured by the multi-layer lines.

7. A logistics system in a fabrication facility, the logistics system comprising:
a plurality of stocker equipment arranged on both sides of a central passage, the stocker equipment including a load port displaced on a side opposite to the central passage, and a rack that provides a space for storing an article; and
a rail that provides a travel path of a transport vehicle that loads and unloads the article to the stocker equipment, the rail including a central rail formed along the central passage, and a branch rail that is branched from the central passage and formed along a periphery of the load port.

8. The logistics system in the fabrication facility according to claim 7, wherein
the branch rail is configured to be branched from the central passage, form along the periphery of the load port, and be joined to the central passage.

9. The logistics system in the fabrication facility according to claim 7, wherein
the transport vehicle travels from the central rail to the branch rail to load and unload the article to the load port.

10. The logistics system in the fabrication facility according to claim 7, wherein
the central rail is configured by a plurality of lines along a horizontal direction.

11. The logistics system in the fabrication facility according to claim 7, wherein
the central rail and the branch rail are configured by multi-layer lines along a vertical direction.

12. The logistics system in the fabrication facility according to claim 11, wherein
the load port is formed under a lower layer line of the branch rail configured by the multi-layer lines.

13. A logistics system in a fabrication facility, the logistics system comprising:
a plurality of stocker equipment arranged on both sides of a central passage;
a rail that provides a travel path of a transport vehicle that loads and unloads an article to the stocker equipment; and
an interface module that is formed across the central passage to convey the article between the stocker equipment,
wherein the stocker equipment includes a load port displaced on a side opposite to the central passage, and a rack that provides a space for storing the article,
the rail includes a central rail formed along the central passage, and a branch rail that is branched from the central passage and formed along a periphery of the load port, and
the interface module is configured to convey the article put into the load port of the stocker equipment to an opposite stocker equipment.

14. The logistics system in the fabrication facility according to claim 13, wherein
the branch rail is configured to be branched from the central passage, form along the periphery of the load port, and be joined to the central passage.

15. The logistics system in the fabrication facility according to claim 13, wherein
the transport vehicle travels from the central rail to the branch rail to load and unload the article to the load port.

16. The logistics system in the fabrication facility according to claim 13, wherein
the central rail is configured by a plurality of lines along a horizontal direction.

17. The logistics system in the fabrication facility according to claim 13, wherein
the interface module includes a pair of conveyors that convey the article in opposite directions.

18. The logistics system in the fabrication facility according to claim 13, wherein
the central rail and the branch rail are configured by multi-layer lines along a vertical direction.

19. The logistics system in the fabrication facility according to claim 18, wherein
the load port is formed under a lower layer line of the branch rail configured by the multi-layer lines.

20. The logistics system in the fabrication facility according to claim 18, wherein
the interface module is formed under a lower layer line of the branch rail.
